(19) United States
(12) Patent Application Publication
(10) Pub. No.: US 2024/0276861 A1
(43) Pub. Date: Aug. 15, 2024

(54) STRETCHABLE DISPLAY APPARATUS

(71) Applicants: Sungwoo Nam, Gwacheon-si (KR); Samsung Display Co., Ltd., Yongin-si (KR)

(72) Inventors: Jangyeol Yoon, Yongin-si (KR); Sungwoo Nam, Gwacheon-si (KR); Seongwon Kim, Yongin-si (KR); Dongchul Shin, Yongin-si (KR)

(21) Appl. No.: 18/417,820

(22) Filed: Jan. 19, 2024

(30) Foreign Application Priority Data
Feb. 9, 2023 (KR) 10-2023-0017261

(51) Int. Cl. H10K 77/10; H10K 59/131; H10K 59/35; H10K 102/00

(52) U.S. Cl. CPC H10K 77/111; H10K 59/131; H10K 59/352; H10K 59/353; H10K 2102/311; H10K 2102/351

(57) ABSTRACT

A stretchable display apparatus includes a substrate including two island regions and a connection region, wherein the two island regions are located apart from each other and the connection region connects the two island regions to each other, sub-pixel circuits arranged in the two island regions, light-emitting diodes arranged in the two island regions and electrically connected to the sub-pixel circuits, a wiring arranged in the connection region and electrically connected to the sub-pixel circuit arranged in a first island region which is one of the two island regions, and an insulating layer on the wiring, wherein at least one of the connection region of the substrate and the insulating layer includes a step difference.

This application claims priority to Korean Patent Application No. 10-2023-0017261, filed on Feb. 9, 2023, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a stretchable display apparatus.

### 2. Description of the Related Art

Display apparatuses that visually display various electrical signals have been developed, and some display apparatuses that have excellent characteristics such as small thickness, small weight, low power consumption, etc. have been introduced. For example, flexible display apparatuses that are foldable or rollable into a roll shape have been introduced.

### SUMMARY

One or more embodiments include a structure for a display apparatus, and more particularly, for a stretchable display apparatus.

Additional aspects will be set forth in part in the description which follows and, in part, will be apparent from the description, or may be learned by practice of the presented embodiments.

According to one or more embodiments, a stretchable display apparatus includes a substrate including two island regions and a connection region, wherein the two island regions are located apart from each other and the connection region connects the two island regions to each other. The stretchable display apparatus further includes sub-pixel circuits arranged in the two island regions, light-emitting diodes arranged in the two island regions and electrically connected to the sub-pixel circuits. The stretchable display apparatus further includes a wiring arranged in the connection region and electrically connected to the sub-pixel circuit arranged in a first island region which is one of the two island regions, and an insulating layer disposed on the wiring, wherein at least one of the connection region of the substrate and the insulating layer includes a step difference.

In an embodiment, the connection region of the substrate may have a first length extending in a lengthwise direction of the connection region and a first width that is directed perpendicular to the first length, wherein the first length may be greater than the first width.

In an embodiment, the connection region of the substrate may include a first portion located adjacent to the first island region, and a second portion located away from the first island region, wherein the second portion may have a thickness which is less than a thickness of the first portion.

In an embodiment, the second portion of the connection region of the substrate may include a concave portion with respect to the first portion, wherein a maximum value of a depth of the concave portion may be about 5 μm.

In an embodiment, a maximum value of a width of the second portion of the connection region of the substrate may be about 0.5 times the first width of the connection region of the substrate.

In an embodiment, the insulating layer disposed in the connection region of the substrate may include a first portion adjacent to the first island region, and a second portion located away from the first island region, wherein the second portion may have a thickness which is less than a thickness of the first portion.

In an embodiment, the second portion of the insulating layer may include a concave portion with respect to the first portion, wherein a maximum value of a depth of the concave portion may be about 3 μm.

In an embodiment, the insulating layer may have a second width directed in a same direction as a direction of the first width of the connection region of the substrate, wherein a maximum value of a width of the second portion of the insulating layer may be about 0.5 times the second width.

In an embodiment, the insulating layer may include an organic insulating material.

In an embodiment, the insulating layer may extend to the first island region of the substrate, and a portion of the insulating layer located in the first island region may be disposed between a transistor of a sub-pixel circuit arranged in the first island region and a first electrode of a light-emitting diode electrically connected to the transistor.

In an embodiment, the first island region of the substrate may include a step difference located in an edge of the first island region.

According to one or more embodiments, a stretchable display apparatus includes a plurality of island portions each including a sub-pixel circuit and a light-emitting diode electrically connected to the sub-pixel circuit, and a connection portion connecting two adjacent island portions to each other among the plurality of island portions, wherein the connection portion includes a wiring electrically connected to a sub-pixel circuit of a first island portion, which is one of the two adjacent island portions, a lower layer disposed under the wiring, and an upper layer disposed on the wiring, and wherein at least one of the lower layer and the upper layer of the connection portion includes a step difference.

In an embodiment, the connection portion may include a first side and a second side, wherein the first side is disposed adjacent to the first island portion, and the second side is located away from the first island portion, and at least one of the upper layer and the lower layer of the connection portion may include a first portion located adjacent to the first side, and a second portion located adjacent to the second side, and wherein the second portion may include a concave portion with respect to the first portion.

In an embodiment, a maximum value of a width of the second portion may be about 0.5 times a width of the connection portion ranging from the first side of the connection portion to the second side.

In an embodiment, the lower layer of the connection portion may include the first portion and the second portion, wherein a maximum value of a depth of the concave portion may be about 5 μm.

In an embodiment, the upper layer of the connection portion may include the first portion and the second portion, wherein a maximum value of a depth of the concave portion may be about 3 μm.

In an embodiment, the lower layer may be a substrate including polymer resin.

In an embodiment, the upper layer may be an organic insulating layer.

In an embodiment, the first island portion may include a first lower layer and a first upper layer, wherein the first lower layer includes a same material as a material of the lower layer of the connection portion, and the first upper layer includes a same material as a material of the upper layer of the connection portion, and at least one of the first lower layer and the first upper layer of the first island portion may include a step difference.

In an embodiment, the stretchable display apparatus may further include an insulating layer disposed on the wiring.

### BRIEF DESCRIPTION OF THE DRAWINGS

The above and other aspects, features, and advantages of embodiments of the invention will be more apparent from the following description taken in conjunction with the accompanying drawings, in which:

FIG. 1 is a perspective view of a stretchable display apparatus, according to an embodiment;

FIG. 2A is a perspective view showing a first state in which the display apparatus of FIG. 1 is stretched in a first direction, according to an embodiment;

FIG. 2B is a perspective view showing a second state in which the display apparatus of FIG. 1 is stretched in a second direction, according to an embodiment;

FIG. 3 is a schematic equivalent circuit diagram of a light-emitting diode of a display apparatus and a sub-pixel circuit electrically connected to the light-emitting diode, according to an embodiment;

FIG. 4 is a schematic enlarged plan view of a portion of the display area of a display apparatus, according to an embodiment;

FIG. 5 is a cross-sectional view of a portion of a display apparatus, taken along line V-V′ of FIG. 4, according to an embodiment;

FIG. 6A is a cross-sectional view of a portion of a display apparatus, taken along line VI-VI′ of FIG. 4, according to an embodiment;

FIG. 6B is a cross-sectional view of a portion of a display apparatus, taken along line VI-VI′ of FIG. 4, according to an embodiment;

FIG. 7A is an enlarged plan view of a portion of a display area of a display apparatus, showing a step difference of a connection portion, according to an embodiment;

FIG. 7B is an enlarged plan view of a portion of a display area of a display apparatus, showing a step difference of a connection portion, according to an embodiment;

FIG. 8 is a plan view of a portion of a display area of a display apparatus, according to an embodiment; and

FIG. 9 is a cross-sectional view of the display area, taken along line IX-IX′ of FIG. 8, according to an embodiment.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b and c” or “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the invention is not limited to the following embodiments and may be embodied in various forms.

Hereinafter, embodiments will be described with reference to the accompanying drawings, wherein like reference numerals refer to like elements throughout and a repeated description thereof is omitted.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

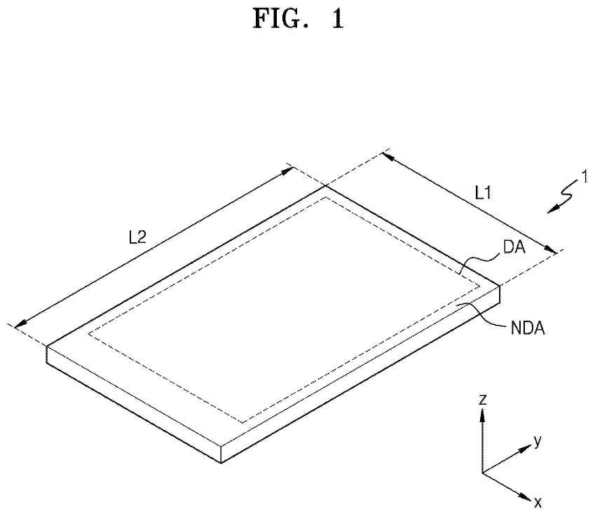

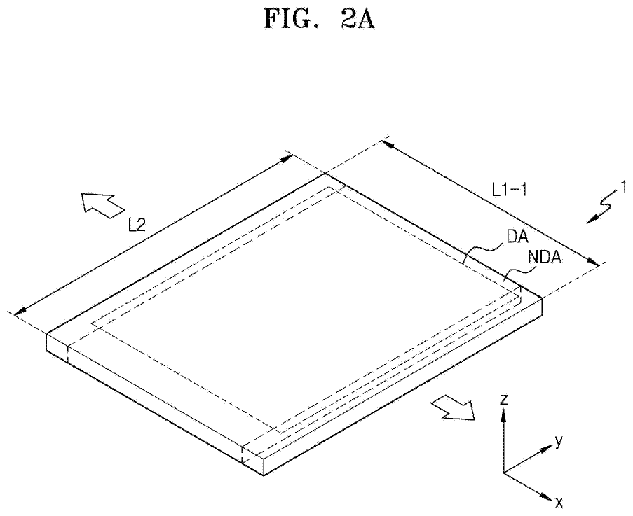

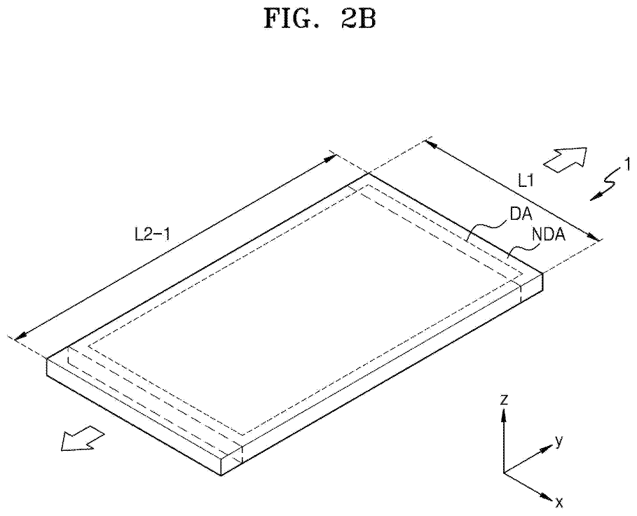

FIG. 1 is a perspective view of a stretchable display apparatus 1 (hereinafter, referred to as a display apparatus) according to an embodiment. FIG. 2A is a perspective view showing a first state in which the display apparatus 1 of FIG. 1 is stretched in a first direction according to an embodiment. FIG. 2B is a perspective view showing a second state in which the display apparatus 1 of FIG. 1 is stretched in a second direction according to an embodiment.

In an embodiment and referring to FIG. 1, the display apparatus 1 may include a display area DA and a non-display area NDA. The display area DA may include a plurality of sub-pixels. The display apparatus 1 may be configured to display images by using light emitted from the plurality of sub-pixels. The non-display area NDA may be adjacent to the display area DA. In an embodiment, the non-display area NDA may surround the display area DA entirely.

In an embodiment, the display apparatus 1 may include a first side L1 extending in the first direction and a second side L2 extending in the second direction. The first side L1 and the second side L2 may each be edges of the display apparatus 1. The first direction and the second direction may cross each other. As an example, the first direction and the second direction may form an acute angle. As another example, the first direction and the second direction may form an obtuse angle and/or be perpendicular to each other. Hereinafter, the case where the first direction is an x direction or a-x direction and the second direction is a y direction or a-y direction is mainly described in detail.

In an embodiment, the display apparatus 1 may be a stretchable display apparatus. As shown in FIG. 2A, the display apparatus 1 may stretch in the first direction (e.g., the x direction or the-x direction) when a tensile force is applied to the display apparatus 1 in the first direction (e.g., the x direction or the-x direction). In this case, a first side L1-1 of FIG. 2A may be greater than the first side L1 of FIG. 1. The display area DA and the non-display area NDA may each stretch in the first direction (e.g., the x direction or the −x direction). In another embodiment, when a contraction force is applied to the display apparatus 1 in the first direction (e.g., the x direction or the −x direction), the display apparatus 1 may contract in the first direction (e.g., the x direction or the −x direction). In this case, the first side L1-1 of FIG. 2A may be less than the first side L1 of FIG. 1. The display area DA and the non-display area NDA may each contract in the first direction (e.g., the x direction or the −x direction).

In an embodiment and referring to FIG. 2B, when a tensile force is applied to the display apparatus 1 in the second direction (e.g., the y direction or the −y direction), the display apparatus 1 may stretch in the second direction (e.g., the y direction or the −y direction). In this case, a second side L2-1 of FIG. 2B may be greater than the second side L2 of FIG. 1. The display area DA and the non-display area NDA may each stretch in the second direction (e.g., the y direction or the −y direction). In another embodiment, when a contraction force is applied to the display apparatus 1 in the second direction (e.g., the y direction or the −y direction), the display apparatus 1 may contract in the second direction (e.g., the y direction or the −y direction). In this case, the second side L2-1 of FIG. 2B may be less than the second side L2 of FIG. 1. The display area DA and the non-display area NDA may each contract in the second direction (e.g., the y direction or the −y direction). When a tensile force or a contraction force is applied to the display apparatus 1 as described above, the display apparatus 1 may be transformed into various shapes.

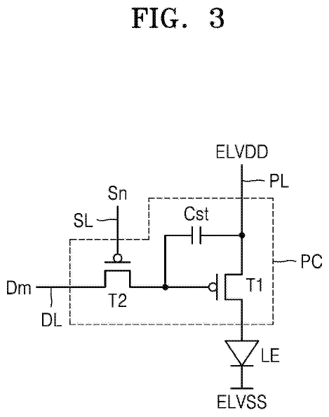

FIG. 3 is a schematic equivalent circuit diagram of one of the light-emitting diodes LE of the display apparatus 1 and a sub-pixel circuit PC electrically connected to the light-emitting diode LE according to an embodiment.

In an embodiment and referring to FIG. 3, the sub-pixel circuit PC electrically connected to the light-emitting diode LE may include a driving transistor T1, a switching transistor T2, and a storage capacitor Cst.

In an embodiment, the switching transistor T2 may be connected to a scan line SL and a data line DL, and configured to transfer a data signal Dm to the driving transistor T1 according to a scan signal Sn, wherein the data signal Dm is input from the data line DL, and the scan signal Sn is input from the scan line SL.

In an embodiment, the storage capacitor Cst may be connected to the switching transistor T2 and a driving voltage line PL and configured to store a voltage corresponding to a difference between a voltage transferred from the switching transistor T2 and a first power voltage ELVDD supplied to the driving voltage line PL.

In an embodiment, the driving transistor T1 may be connected to the driving voltage line PL and the storage capacitor Cst and configured to control a driving current according to the voltage stored in the storage capacitor Cst, the driving current flowing from the driving voltage line PL to the light-emitting diode LE. The light-emitting diode LE may be configured to emit light having a preset brightness according to the driving current. An opposite electrode (e.g., a cathode) of the light-emitting diode LE may receive a second power voltage ELVSS.

In an embodiment, although it is shown in FIG. 3 that the sub-pixel circuit PC includes two transistors and one storage capacitor, the sub-pixel circuit PC may include any number of transistor and/or capacitors, such as three or more transistors.

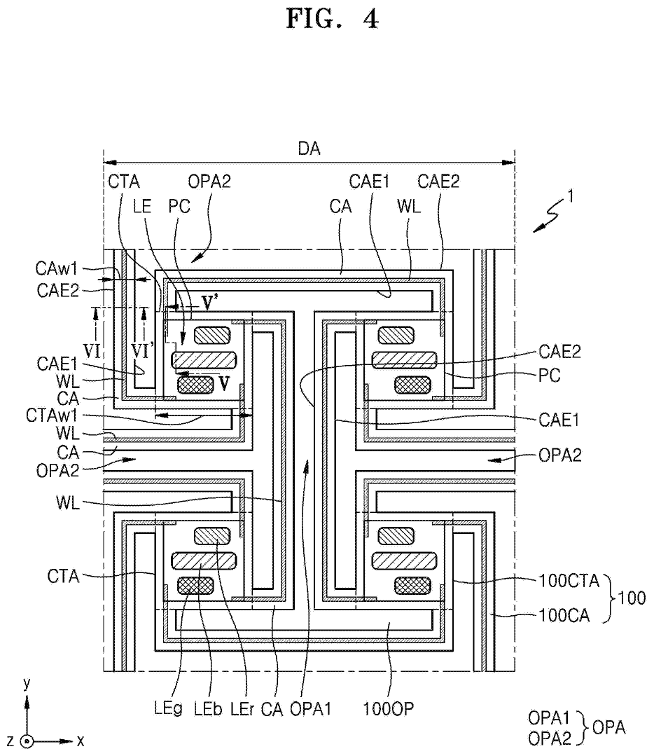

FIG. 4 is a schematic enlarged plan view of a portion of the display area DA of the display apparatus 1 according to an embodiment.

In an embodiment and referring to FIG. 4, the display apparatus 1 may include island portions CTA, connection portions CA, and/or openings OPA.

In an embodiment, the island portion CTA is a region in which the light-emitting diode LE may be arranged. The plurality of island portions CTA may be arranged apart from each other. In an embodiment, it is shown in FIG. 4 that a red light-emitting diode LEr, a green light-emitting diode LEg, and a blue light-emitting diode LEb are arranged in each island portion CTA.

In an embodiment, the connection portion CA may extend between adjacent island portions CTA. The connection portion CA may connect the adjacent island portions CTA to each other. As an example, it is shown in FIG. 4 that each island portion CTA is connected to four connection portions CA. Four connection portions CA connected to one island portion CTA extend in different directions. Each connection portion CA may be connected to another island portion CTA arranged adjacent to the one island portion CTA. As an example, one island portion CTA may be connected to four island portions CTA surrounding the one island portion CTA through four connection portions CA. The adjacent island portions CTA and the connection portion CA may be integrally connected to each other.

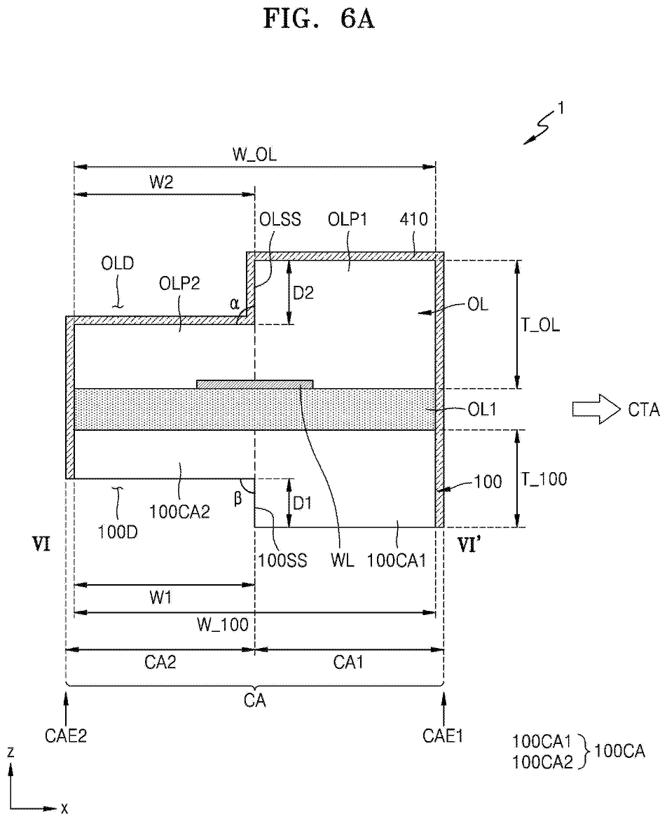

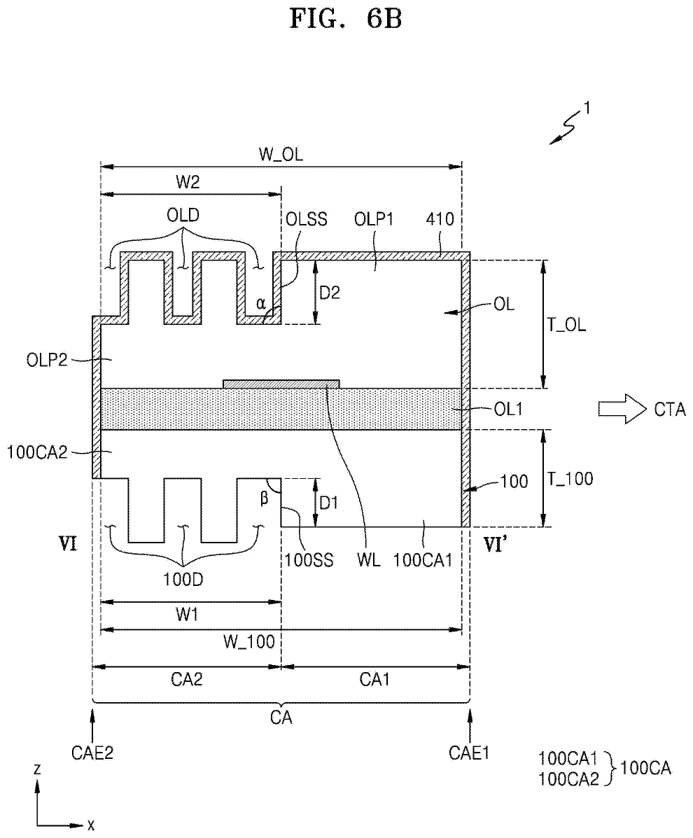

In an embodiment, each connection portion CA may extend in a lengthwise direction to connect adjacent island portions CTA to each other. Each connection portion CA may be bent. As an example, one of the connection portions CA shown in FIG. 6A and FIG. 6B may be bent from the second direction (e.g., the +y direction or the −y direction) to the first direction (e.g., the x direction or the −x direction) and then be bent again in a reverse second direction (e.g., the −y direction or the +y direction). Another connection portion CA may be bent from the first direction (e.g., the +x direction or the −x direction) to the second direction (e.g., the +y direction or the −y direction) and then be bent again in a reverse first direction e.g., the −x direction or the +x direction). Although it is shown in FIG. 4 that a bent corner portion of the connection portion CA has a right angle, the bent corner portion of the connection portion CA may have various angles in another embodiment. In another embodiment, the bent corner portion of the connection portion CA may have a round shape.

In an embodiment, a bent direction of the connection portion CA may represent the lengthwise direction of the connection portion CA. The connection portion CA may have a width CAw1 that may be less than a length extending between the adjacent island portions CTA. The width CAw1 of the connection portion CA may be less than a width CTAw1 of the island portion CTA. The length of the connection portion CA may be defined as a value obtained by dividing a sum of the lengths of the first and second sides CAE1 and CAE2 of the connection portion CA by 2. The first side CAE1 of the connection portion CA may be a side relatively adjacent to the island portion CTA, and the second side CAE2 is an opposite side of the first side CAE1 and may be a side relatively away from the island portion CTA. In other words, the first side CAE1 of the connection portion CA may be a side relatively adjacent to the island portion CTA with respect to a wiring WL, and the second side CAE2 may be a side relatively away from the island portion CTA with respect to the wiring WL.

In an embodiment, each connection portion CA may include the wiring WL. The wiring WL may be electrically connected to the sub-pixel circuit PC located in each of the island portions CTA respectively located in two opposite ends of the connection portion CA. The wiring WL may include a signal line and/or a voltage line configured to provide signals and/or voltages to the sub-pixel circuit PC connected thereto. The wiring WL may have a width that is less than the width CAw1 of the connection portion CA.

In an embodiment, although it is shown in FIG. 4 that each connection portion CA includes one wiring WL, the embodiment is not limited thereto. In another embodiment, each connection portion CA may include a plurality of wirings WL.

In an embodiment, the openings OPA may be a kind of through holes passing through the display apparatus 1. Each opening OPA may be surrounded by four island portions CTA and four connection portions CA. As an example, each opening OPA may be surrounded by one side of each of four island portions CTA and each of four connection portions CA. In a embodiment, each opening OPA may have a shape that resembles the shape obtained by rotating an alphabet letter “H” by about 90° or that resembles a shape of an alphabet letter “H”.

In an embodiment, the openings OPA may be located apart from each other. In an embodiment, it is shown in FIG. 4 that an opening OPA1 (hereinafter, referred to as a first opening) having a shape that resembles the shape obtained by rotating an alphabet letter “H” by about 90° and an opening OPA2 (hereinafter, referred to as a second opening) having a shape of about an alphabet letter “H” are alternately arranged in the ±x directions and the ±y directions. In the present specification, the opening OPA may represent the first opening OPA1 and/or the second opening OPA2.

In an embodiment and as described above with reference to FIGS. 2A and 2B, when a force is applied to the display apparatus 1, the shape of the opening OPA, for example, the first opening OPA1 and/or the second opening OPA2 changes, and thus, the occurrence of stress is easily reduced while the display apparatus 1 is transformed. Accordingly, abnormal transformation of the display apparatus 1 may be prevented and durability of the display apparatus 1 may be improved.

In an embodiment, the structure of the display apparatus 1 including the island portions CTA, the connection portions CA, and the openings OPA shown in FIG. 4 may be understood as the shape of the substrate 100 provided to the display apparatus 1. As an example, the substrate 100 may include an island region 100CTA corresponding to the island portions CTA, a connection region 100CA corresponding to the connection portions CA, and openings 100OP corresponding to the openings OPA.

In an embodiment, the island regions 100CTA of the substrate 100 may be located apart from each other and be connected to each other by the connection regions 100CA. The connection region 100CA may extend between adjacent island regions 100CTA and form one body with the island regions 100CTA.

In an embodiment, it may be considered that descriptions of characteristics of the island portions CTA, the connection portions CA, and the openings OPA of the display apparatus 1 described above with reference to FIG. 4 are descriptions of characteristics of the island regions 100CTA, the connection regions 100CA, and the opening 100OP of the substrate 100. In other words, the above description of the connection portion CA may correspond to description of the connection region 100CA of the substrate 100, and the above description of the opening OPA may correspond to description of the opening 100OP of the substrate 100. As an example, when the connection portion CA may have a shape in which the length of the connection portion CA is greater than the width CAw1, it may be considered that the connection region 100CA of the substrate 100 may have a shape in which the length of the connection region 100CA is greater than the width of the connection region 100CA. Here, as described above, the width represents a value in a direction that is perpendicular to the length.

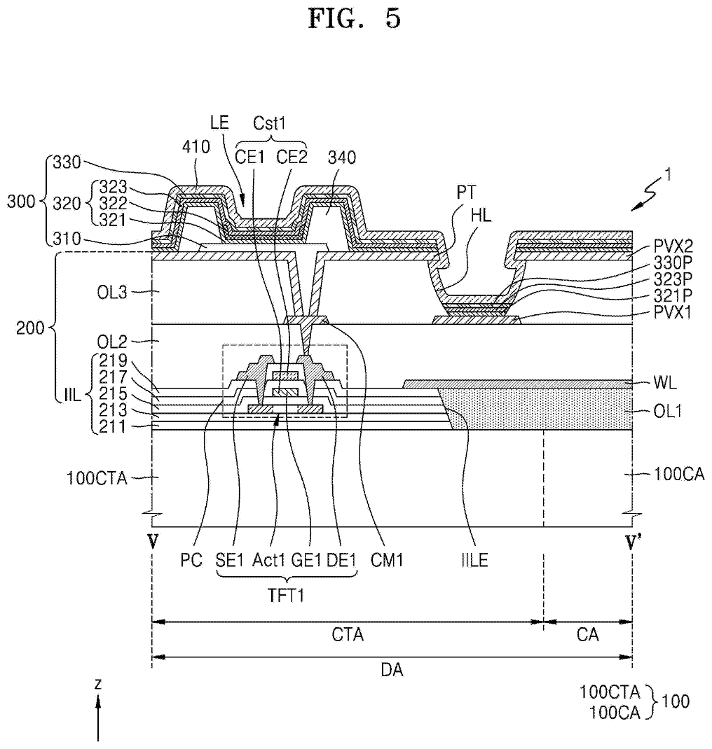

FIG. 5 is a cross-sectional view of a portion of the display apparatus 1, taken along line V-V′ of FIG. 4 according to an embodiment.

In an embodiment and referring to FIG. 5, the display area DA of the display apparatus 1 may include the island portion CTA and the connection portion CA, and the island portion CTA may include the light-emitting diode LE and the sub-pixel circuit PC electrically connected to the light-emitting diode LE. The sub-pixel circuit PC may be disposed between the substrate 100 and the light-emitting diode LE, for example, between the island region 100CTA of the substrate 100 and the light-emitting diode LE.

In an embodiment, the substrate 100 may include polymer resin such as polyethersulfone, polyarylate, polyetherimide, polyethylene naphthalate, polyethylene terephthalate, polyphenylene sulfide, polyimide, polycarbonate, cellulose tri acetate, and/or cellulose acetate propionate. In an embodiment, the substrate 100 may have a multi-layered structure including a base layer and a barrier layer, wherein the base layer includes the above polymer resin and/or the barrier layer includes an inorganic insulating material. The substrate 100 including the polymer resin is flexible, rollable, and/or bendable. In another embodiment, the substrate 100 may include glass.

In an embodiment, a circuit layer 200 may be disposed on the substrate 100. The circuit layer 200 may include the sub-pixel circuit PC, a wiring WL, an inorganic insulating layer IIL, a first organic insulating layer OL1, a second organic insulating layer OL2, a first contact electrode CM1, a third organic insulating layer OL3, a first inorganic layer PVX1, and a second inorganic layer PVX2. The sub-pixel circuit PC may include a first transistor TFT1 and a first storage capacitor Cst1. The first transistor TFT1 may include a first semiconductor layer Act1, a first gate electrode GE1, a first source electrode SE1, and a first drain electrode DE1. The first storage capacitor Cst1 may include a first capacitor electrode CE1 and a second capacitor electrode CE2.

In an embodiment, the inorganic insulating layer IIL may be disposed on the substrate 100. The inorganic insulating layer IIL may include a barrier layer 211, a buffer layer 213, a first gate insulating layer 215, a second gate insulating layer 217, and an interlayer insulating layer 219.

In an embodiment, the barrier layer 211 may be disposed on the substrate 100, for example, in the island region 100CTA of the substrate 100. The barrier layer 211 may be a layer configured to prevent and/or reduce penetration of external foreign materials. The barrier layer 211 may be a single layer or a multi-layer including an inorganic material such as silicon nitride, silicon oxide, and/or silicon oxynitride.

In an embodiment, the buffer layer 213 may be disposed on the barrier layer 211. The buffer layer 213 may be a single layer or a multi-layer including an inorganic material such as silicon nitride, silicon oxide, and/or silicon oxynitride.

In an embodiment, the first semiconductor layer Act1 may be disposed on the buffer layer 213. The first semiconductor layer Act1 may include polycrystalline silicon. Alternatively, the first semiconductor layer Act1 may include amorphous silicon, an oxide semiconductor, and/or an organic semiconductor. In an embodiment, the first semiconductor layer Act1 may include a channel region, a drain region, and a source region, the drain region and the source region being on two opposite sides of the channel region.

In an embodiment, the first gate insulating layer 215 may be disposed on the first semiconductor layer Act1 and the buffer layer 213. The first gate insulating layer 215 may include an inorganic insulating material such as silicon oxide, silicon nitride, silicon oxynitride, aluminum oxide, titanium oxide, tantalum oxide, hafnium oxide, and/or zinc oxide. Zinc oxide may include zinc oxide (ZnO) and/or zinc peroxide (ZnO₂).

In an embodiment, the first gate electrode GE1 may be disposed on the first gate insulating layer 215. The first gate electrode GE1 may overlap the channel region of the first semiconductor layer Act1. The first gate electrode GE1 may include a low-resistance metal material. In an embodiment, the first gate electrode GE1 may include a conductive material including molybdenum (Mo), aluminum (Al), copper (Cu), and/or titanium (Ti) and include a single layer or a multi-layer including the above materials.

In an embodiment, the second gate insulating layer 217 may be disposed on the first gate electrode GE1 and the first gate insulating layer 215. The second gate insulating layer 217 may include an inorganic insulating material such as silicon nitride, silicon oxide, and/or silicon oxynitride.

In an embodiment, the second capacitor electrode CE2 may be disposed on the second gate insulating layer 217. The second capacitor electrode CE2 may overlap the first gate electrode GE1. In this case, the first gate electrode GE1 may serve as the first capacitor electrode CE1. Although it is shown in FIG. 5 that the first storage capacitor Cst1 overlaps the first transistor TFT1, the first storage capacitor Cst1 may not overlap the first transistor TFT1 in another embodiment. In this case, the first capacitor electrode CE1 and the first gate electrode GE1 may be separate electrodes. The second capacitor electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

In an embodiment, the interlayer insulating layer 219 may be disposed on the second capacitor electrode CE2 and the second gate insulating layer 217. The interlayer insulating layer 219 may include an inorganic insulating material such as silicon oxide, silicon nitride, and/or silicon oxynitride.

In an embodiment, the first source electrode SE1 and the first drain electrode DE1 may each be disposed on the interlayer insulating layer 219. The first source electrode SE1 and the first drain electrode DE1 may each be connected to the first semiconductor layer Act1 through a contact hole provided in the first gate insulating layer 215, the second gate insulating layer 217, and the interlayer insulating layer 219. At least one of the first source electrode SE1 and the first drain electrode DE1 may include a conductive material including molybdenum (Mo), aluminum (Al), copper (Cu), and/or titanium (Ti) and include a single layer or a multi-layer including the above materials. In an embodiment, at least one of the first source electrode SE1 and the first drain electrode DE1 may have a multi-layered structure of Ti/Al/Ti.

In an embodiment, the inorganic insulating layer IIL in the display area DA may overlap the island region 100CTA of the substrate 100 and may not overlap the connection region 100CA of the substrate 100. The inorganic insulating layer IIL may include an end portion IILE facing the connection region 100CA. In other words, the connection portion CA may not include the inorganic insulating layer IIL which may be relatively vulnerable to cracks. Accordingly, when the display apparatus 1 stretches or contracts, damage to the connection portion CA that is relatively much transformed may be prevented. Although it is shown in FIG. 5 that the end portion IILE of the inorganic insulating layer IIL does not have a step difference, the end portion IILE of the inorganic insulating layer IIL may have a step difference in another embodiment.

In an embodiment, the first organic insulating layer OL1 may be arranged in the island region 100CTA and the connection region 100CA of the substrate 100. The first organic insulating layer OL1 may cover the end portion IILE of the inorganic insulating layer IIL. The first organic insulating layer OL1 may be configured to reduce a height difference while the wiring WL extends from the island region 100CTA of the substrate 100 to the connection region 100CA. The first organic insulating layer OL1 may be configured to absorb stress that may be applied to the wiring WL. The first organic insulating layer OL1 may include an organic material. The first organic insulating layer OL1 may include an organic insulating material including a general-purpose polymer such as polymethylmethacrylate (PMMA) and/or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a blend thereof.

In an embodiment, the wiring WL may be disposed on the inorganic insulating layer IIL and/or the first organic insulating layer OL1. The wiring WL may extend from the island region 100CTA of the substrate 100 to the connection region 100CA. Although not shown in FIG. 5, the wiring WL may be electrically connected to the sub-pixel circuit PC. The wiring WL may include a conductive material including molybdenum (Mo), aluminum (Al), copper (Cu), and/or titanium (Ti) and have a single-layered structure or a multi-layered structure including the above materials. In an embodiment, the wiring WL may have a multi-layered structure of Ti/Al/Ti.

In an embodiment, the second organic insulating layer OL2 may be disposed on the inorganic insulating layer IIL, the first source electrode SE1, the first drain electrode DE1, and/or the wiring WL. The second inorganic insulating layer OL2 may include an organic material. The second organic insulating layer OL2 may include an organic insulating material including a general-purpose polymer such as polymethylmethacrylate (PMMA) and/or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a blend thereof.

In an embodiment, the wiring WL may be disposed between the first organic insulating layer OL1 and the second organic insulating layer OL2 in the connection region 100CA of the substrate 100. When the shape of the display apparatus 1 is transformed, the connection region 100CA of the substrate 100 may be transformed. In this case, there may be a stress neutral plane in the display apparatus 1. Because the wiring WL is disposed between the first organic insulating layer OL1 and the second organic insulating layer OL2, the wiring WL may be located on the stress neutral plane, and stress applied to the wiring WL may be reduced.

In an embodiment, the first contact electrode CM1 may be disposed on the second organic insulating layer OL2. The first contact electrode CM1 may be electrically connected to the sub-pixel circuit PC through a contact hole of the second organic insulating layer OL2. The first contact electrode CM1 may include a conductive material including molybdenum (Mo), aluminum (Al), copper (Cu), and/or titanium (Ti) and have a single-layered structure or a multi-layered structure including the above materials. The first contact electrode CM1 may have a multi-layered structure of Ti/Al/Ti.

In an embodiment, the third organic insulating layer OL3 may be disposed on the second organic insulating layer OL2 and the first contact electrode CM1. The third inorganic insulating layer OL3 may include an organic material. The third organic insulating layer OL3 may include an organic insulating material including a general-purpose polymer such as polymethylmethacrylate (PMMA) and/or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a blend thereof.

In an embodiment, the first inorganic layer PVX1 may be disposed between the second organic insulating layer OL2 and the third organic insulating layer OL3. The first inorganic layer PVX1 may include an inorganic material.

In an embodiment, the third organic insulating layer OL3 may include a hole HL. The hole HL may expose the first inorganic layer PVX1. The hole HL may be formed by etching the third organic insulating layer OL3. The first inorganic layer PVX1 may prevent or reduce over-etching of an element disposed under the first inorganic layer PVX1.

In an embodiment, the second inorganic layer PVX2 may be disposed on the third organic insulating layer OL3. The second inorganic layer PVX2 may include a protrusion tip PT protruding to the center of the hole HL. The lower surface of the protrusion tip PT of the second inorganic layer PVX2 may be exposed in the hole HL.

In an embodiment, a light-emitting diode layer 300 may be disposed on the circuit layer 200. The light-emitting diode layer 300 may include the light-emitting diode LE and a bank layer 340. The light-emitting diode LE may be an organic light-emitting diode. The light-emitting diode LE may include a first electrode 310, an intermediate layer 320, and a second electrode 330, which is an opposite electrode.

In an embodiment, the first electrode 310 of the light-emitting diode LE may be electrically connected to the first contact electrode CM1 through a contact hole of the third organic insulating layer OL3. The first electrode 310 may include a conductive oxide such as indium tin oxide (ITO), indium zinc oxide (IZO), zinc oxide (ZnO), indium oxide (In₂O₃), indium gallium oxide (IGO), and/or aluminum zinc oxide (AZO). In another embodiment, the first electrode 310 may include a reflective layer including silver (Ag), magnesium (Mg), aluminum (Al), platinum (Pt), palladium (Pd), gold (Au), nickel (Ni), neodymium (Nd), iridium (Ir), chrome (Cr), and/or a compound thereof. In another embodiment, the first electrode 310 may further include a layer on/under the reflective layer, wherein the layer may include ITO, IZO, ZnO, and/or In₂O₃.

In an embodiment, the bank layer 340 may cover the edges of the first electrode 310. The bank layer 340 may include an emission opening, and the emission opening may overlap the first electrode 310. The emission opening may define an emission area of light emitted from the light-emitting diode LE. The bank layer 340 may include an organic insulating material and/or an inorganic insulating material. In an embodiment, the bank layer 340 may include a light-blocking material.

In an embodiment, the intermediate layer 320 may be disposed on the first electrode 310, the bank layer 340, and/or the second inorganic layer PVX2. The intermediate layer 320 may include an emission layer 322. The emission layer 322 may overlap the first electrode 310. The emission layer 322 may include a polymer organic material and/or a low molecular weight organic material configured to emit light of a preset color.

In an embodiment, the intermediate layer 320 may further include a first functional layer 321 and/or a second functional layer 323. The first functional layer 321 may be disposed between the first electrode 310 and the emission layer 322. The first functional layer 321 may include a hole transport layer (HTL) and/or a hole injection layer (HIL). The second functional layer 323 may be disposed between the emission layer 322 and the second electrode 330. The second functional layer 323 may include an electron transport layer (ETL) and/or an electron injection layer (EIL). In an embodiment, the first functional layer 321 and the second functional layer 323 may overlap the island region 100CTA and the connection region 100CA of the substrate 100 entirely.

In an embodiment, the second electrode 330 may be disposed on the first electrode 310, the intermediate layer 320, and/or the bank layer 340. The second electrode 330 may include a conductive material having a low work function. As an example, the second electrode 330 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), and/or an alloy thereof. Alternatively, the second electrode 330 may further include a layer on the (semi) transparent layer, wherein the layer may include ITO, IZO, ZnO, and/or In₂O₃.

In an embodiment, an organic material included in the intermediate layer 320, for example, the first functional layer 321 and/or the second functional layer 323 may be disconnected by the protrusion tip PT. The first functional layer 321 and the second functional layer 323 including an organic material may serve as a path through which external oxygen and/or moisture may penetrate. In an embodiment, because the second inorganic layer PVX2 has the protrusion tip PT protruding to the center of the hole HL, the first functional layer 321 and the second functional layer 323 may each be disconnected around the hole HL. Accordingly, introduction of moisture and/or oxygen may be prevented or reduced, wherein the moisture and/or oxygen progresses toward the light-emitting diode LE from the outside.

In an embodiment, a first dummy functional layer 321P and/or a second dummy functional layer 323P may be disposed in the hole HL, wherein the first dummy functional layer 321P may include the same material as a material of the first functional layer 321, and/or the second dummy functional layer 323P may include the same material as a material of the second functional layer 323. In an embodiment, a dummy opposite electrode 330P may be disposed on the first dummy functional layer 321P and/or the second dummy functional layer 323P, wherein the dummy opposite electrode 330P may include the same material as a material of the second electrode 330.

In an embodiment, an inorganic encapsulation layer 410 may be disposed on the light-emitting diode layer 300. The inorganic encapsulation layer 410 may cover the substrate 100 entirely. As an example, the inorganic encapsulation layer 410 may overlap the island region 100CTA and the connection region 100CA of the substrate 100 continuously and entirely. The inorganic encapsulation layer 410 may be in direct contact with the lower surface of the protrusion tip PT of the second inorganic layer PVX2. Accordingly, introduction of moisture and/or oxygen may be prevented or reduced, wherein the moisture and/or oxygen progresses toward the light-emitting diode LE from the outside.

In an embodiment, an organic encapsulation layer may be disposed on the inorganic encapsulation layer 410 to overlap the light-emitting diode LE. In addition, an additional inorganic encapsulation layer may be further disposed on the organic encapsulation layer.

FIGS. 6A and 6B are cross-sectional views of a portion of the display apparatus 1, taken along line VI-VI′ of FIG. 4 according to an embodiment.

In an embodiment and referring to FIGS. 4 and 6A, the connection portion CA of the display apparatus 1 may include the wiring WL arranged in the connection region 100CA of the substrate 100. The wiring WL may have a width less than the width of the connection region 100CA of the substrate 100. The wiring WL may be disposed on the first organic insulating layer OL1 arranged in the connection region 100CA of the substrate 100 and/or may overlap the organic insulating layer OL.

In an embodiment, the organic insulating layer OL may have a structure of the second organic insulating layer OL2 (see FIG. 5) and/or the third organic insulating layer OL3 (see FIG. 5) described above with reference to FIG. 5. In an embodiment, the second organic insulating layer OL2 and/or the third organic insulating layer OL3 described above with reference to FIG. 5 may be arranged also in the connection region 100CA of the substrate 100. In the case where the second organic insulating layer OL2 and the third organic insulating layer OL3 include the same material, an interface between the second organic insulating layer OL2 and the third organic insulating layer OL3 included in the organic insulating layer OL may be difficult to identify. Although it is described in FIG. 6A that the organic insulating layer OL has a structure of the second organic insulating layer OL2 and the third organic insulating layer OL3 described above with reference to FIG. 5, the embodiment is not limited thereto. In another embodiment, the organic insulating layer OL arranged in the connection region 100CA of the substrate 100 may include a single layer of the second organic insulating layer OL2 (see FIG. 5) and/or a single layer of the third organic insulating layer OL3 (see FIG. 5).

In other words, as shown in FIG. 6A and/or FIG. 6B, the organic insulating layer OL arranged in the connection region 100CA of the substrate 100 may be one body with the second organic insulating layer OL2 and/or the third organic insulating layer OL3 described above with reference to FIG. 5. In addition, in other words, as shown in FIG. 6A and/or FIG. 6B, the organic insulating layer OL arranged in the connection region 100CA of the substrate 100 may extend to the island region 100CTA (see FIG. 5) of the substrate 100 described with reference to FIG. 5. A portion (e.g., a portion of the second organic insulating layer OL2 and/or a portion of the third organic insulating layer OL3) of the organic insulating layer OL extending to the island region 100CTA may be disposed between the first transistor TFT1 (see FIG. 5) and the first electrode 310 (see FIG. 5) of the light-emitting diode LE (see FIG. 5).

In an embodiment, the connection portion CA of the display apparatus 1 may include a lower layer disposed under the wiring WL and an upper layer disposed on the wiring WL. At least one of the lower layer and the upper layer of the connection portion CA may include a step difference. As an example, at least one of the substrate 100 as the lower layer disposed under the wiring WL and the organic insulating layer OL as the upper layer disposed on the wiring WL may include a step difference.

In an embodiment, a portion CA1 (hereinafter, referred to as a first connection portion) of the connection portion CA adjacent to the first side CAE1 may be thicker than a portion CA2 (hereinafter, referred to as a second connection portion) adjacent to the second side CAE2, which is opposite the first side CAE1. Here, as described above with reference to FIG. 4, the first side CAE1 of the connection portion CA is a side relatively adjacent to the island portion CTA, and the second side CAE2 of the connection portion CA is a side located opposite the first side CAE1 with the wiring WL therebetween and is relatively away from the island portion CTA.

In an embodiment, the substrate 100 which is the lower layer of the connection portion CA, for example, the connection region 100CA of the substrate 100 includes a first portion 100CA1 adjacent to the first side CAE1 of the connection portion CA and a second portion 100CA2 adjacent to the second side CAE2 of the connection portion CA. The second portion 100CA2 may be relatively concave with respect to the first portion 100CA1. In other words, the second portion 100CA2 may form a step difference with respect to the first portion 100CA1.

In an embodiment, the second portion 100CA2 of the connection region 100CA of the substrate 100 includes a concave portion 100D. A first depth D1 of the concave portion 100D may be less than a first thickness T_100 of the first portion 100CA1. As an example, a maximum value of the first depth D1 of the concave portion 100D of the second portion 100CA2 may be about 5 μm. In an embodiment, the first depth D1 may be about 0.1 μm to about 5 μm. In other words, a maximum value of a difference between the thickness of the first portion 100CA1 of the connection region 100CA of the substrate 100 and the thickness of the second portion 100CA2 of the connection region 100CA of the substrate 100 may be about 5 μm. An angle (β) between a side surface 100SS of the concave portion 100D and a bottom surface of the concave portion 100D may be about 45° and 135°.

In an embodiment, although it is shown in FIG. 6A that the second portion 100CA2 of the connection region 100CA of the substrate 100 includes the single concave portion 100D, the embodiment is not limited thereto. In another embodiment, as shown in FIG. 6B, the second portion 100CA2 of the connection region 100CA of the substrate 100 may include a plurality of concave portions 100D spaced apart from each other. As described above, a maximum value of the first depth D1 of each concave portion 100D may be about 5 μm.

In an embodiment and referring to FIGS. 6A and 6B, a width W1 of the second portion 100CA2 of the connection region 100CA of the substrate 100 in which the concave portion 100D is located may be less than or equal to about 0.5 times a width W_100 of the connection region 100CA of the substrate 100. In other words, a maximum value of the width W1 of the second portion 100CA2 of the connection region 100CA of the substrate 100 may be about 0.5 times the width W_100 of the connection region 100CA of the substrate 100.

In an embodiment, the organic insulating layer OL, which is an upper layer of the connection portion CA, includes a first portion OLP1 adjacent to the first side CAE1 of the connection portion CA, and a second portion OLP2 adjacent to the second side CAE2 of the connection portion CA. The second portion OLP2 may be relatively concave with respect to the first portion OLP1. In other words, the second portion OLP2 may form a step difference with respect to the first portion OLP1.

In an embodiment, the second portion OLP2 of the organic insulating layer OL includes the concave portion OLD, and a second depth D2 of the concave portion OLD may be less than a first thickness T_OL of the first portion OLP1. As an example, a maximum value of the second depth D2 of the concave portion OLD of the second portion OLP2 may be about 3 μm. In an embodiment, the second depth D2 may be about 0.1 μm to about 3 μm. In other words, a maximum value of a difference between the thickness of the first portion OLP1 of the organic insulating layer OL and the thickness of the second portion OLP2 of the organic insulating layer OL may be about 3 μm. An angle (α) between a side surface OLSS of the concave portion OLD and a bottom surface of the concave portion OLD may be about 45° and about 135°.

In an embodiment, although it is shown in FIG. 6A that the second portion OLP2 of the organic insulating layer OL includes a single concave portion OLD, the embodiment is not limited thereto. In another embodiment, as shown in FIG. 6B, the second portion OLP2 of the organic insulating layer OL may include a plurality of concave portions OLD spaced apart from each other. As described above, a maximum value of the second depth D2 of each concave portion OLD may be about 3 μm.

In an embodiment, referring to FIGS. 6A and 6B, a width W2 of the second portion OLP2 of the organic insulating layer OL including the concave portion OLD may be less than or equal to about 0.5 times a width W_OL of the organic insulating layer OL. Although it is shown in FIGS. 6A and 6B that the width W2 of the second portion OLP2 of the organic insulating layer OL is substantially the same as the width W1 of the second portion 100CA2 of the connection region 100CA of the substrate 100, the embodiment is not limited thereto. The width W2 of the second portion OLP2 of the organic insulating layer OL may be different from the width W1 of the second portion 100CA2 of the connection region 100CA of the substrate 100.

In an embodiment, the inorganic encapsulation layer 410 described above with reference to FIG. 5 may extend to the connection portion CA and overlap the organic insulating layer OL. In an embodiment, the inorganic encapsulation layer 410 may cover not only the upper surface of the organic insulating layer OL but also the lateral surface of the connection portion CA. As an example, the inorganic encapsulation layer 410 may cover the upper surface and two opposite lateral surfaces of the organic insulating layer OL, two opposite lateral surfaces of the first organic insulating layer OL1, and two opposite lateral surfaces of the substrate 100.

In an embodiment, as shown in FIGS. 6A an 6B, because the connection portion CA has a structure of a step difference such that two opposite sides thereof are asymmetrical with respect to a virtual central line between the first side CAE1 and the second side CAE2 of the connection portion CA, strain due to stress applied to the connection portion CA may be reduced, and simultaneously, strength required to maintain the shape of the display apparatus 1 may be secured.

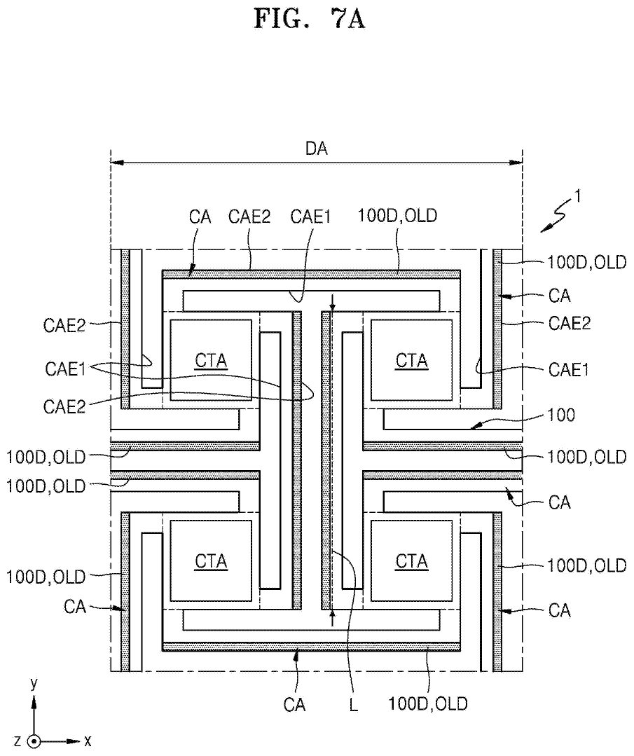

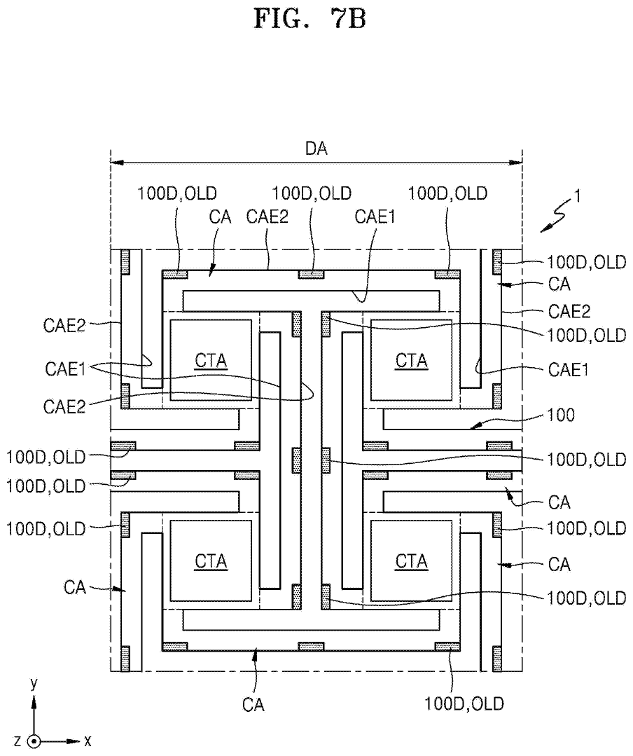

FIGS. 7A and 7B are enlarged plan views of a portion of the display area DA of the display apparatus 1, showing a step difference of a connection portion CA according to an embodiment.

In an embodiment, referring to FIG. 7A, the connection portion CA of the display apparatus 1 includes the first side CAE1 and the second side CAE2 spaced apart from each other in the width direction. The first side CAE1 may be relatively adjacent to the island portion CTA, and the second side CAE2 may be relatively away from the island portion CTA.

In an embodiment, each connection portion CA may include the step difference structure described above with reference to FIGS. 6A and 6B, for example, the concave portion 100D of the substrate 100 (see FIGS. 6A and 6B) and/or the concave portion OLD of the organic insulating layer OL (see FIGS. 6A and 6B). Although it is shown in FIGS. 7A and 7B that, for convenience of description, the connection portion CA includes both the concave portion 100D of the substrate 100 and the concave portion OLD of the organic insulating layer OL, the embodiment is not limited thereto. In another embodiment, the connection portion CA may include the concave portion 100D of the substrate 100 and/or include the concave portion OLD of the organic insulating layer OL.

In an embodiment, as shown in FIGS. 7A and 7B, the concave portion 100D of the substrate 100 and/or the concave portion OLD of the organic insulating layer OL in each connection portion CA may be relatively located away from the island portion CTA.

In other words, the concave portion 100D of the substrate 100 and/or the concave portion OLD of the organic insulating layer OL may be located adjacent to the second side CAE2 of each connection portion CA. That is, the concave portion 100D of the substrate 100 and/or the concave portion OLD of the organic insulating layer OL may be located away from the first side CAE1 of each connection portion CA.

In an embodiment, the concave portion 100D of the substrate 100 and/or the concave portion OLD of the organic insulating layer OL may be continuously located in the lengthwise direction of each connection portion CA as shown in FIG. 7A. In another embodiment, as shown in FIG. 7B, the concave portion 100D of the substrate 100 and/or the concave portion OLD of the organic insulating layer OL may be discontinuously located in the lengthwise direction of each connection portion CA.

In an embodiment, although it is shown in FIG. 7A that the concave portion 100D of the substrate 100 and/or the concave portion OLD of the organic insulating layer OL is formed to have the same length as a distance L from a first bent portion to a second bent portion of the connection portion CA, the embodiment is not limited thereto. In another embodiment, the length of the concave portion 100D of the substrate 100 and/or the concave portion OLD of the organic insulating layer OL may be less than the distance L.

In an embodiment, as shown in FIG. 7B, even though the concave portion 100D of the substrate 100 and/or the concave portion OLD of the organic insulating layer OL are discontinuously arranged, the concave portion 100D of the substrate 100 and/or the concave portion OLD of the organic insulating layer OL may be provided to a portion of the connection portion CA which is relatively vulnerable to stress. As an example, because a region at a point of about ½ of the length of the connection portion CA and/or a region at a bent point of the connection portion CA are regions that are relatively vulnerable to stress, the concave portion 100D of the substrate 100 and/or the concave portion OLD of the organic insulating layer OL may be located at the above points as shown in FIG. 7B, and thus, strain at the above points may be reduced.

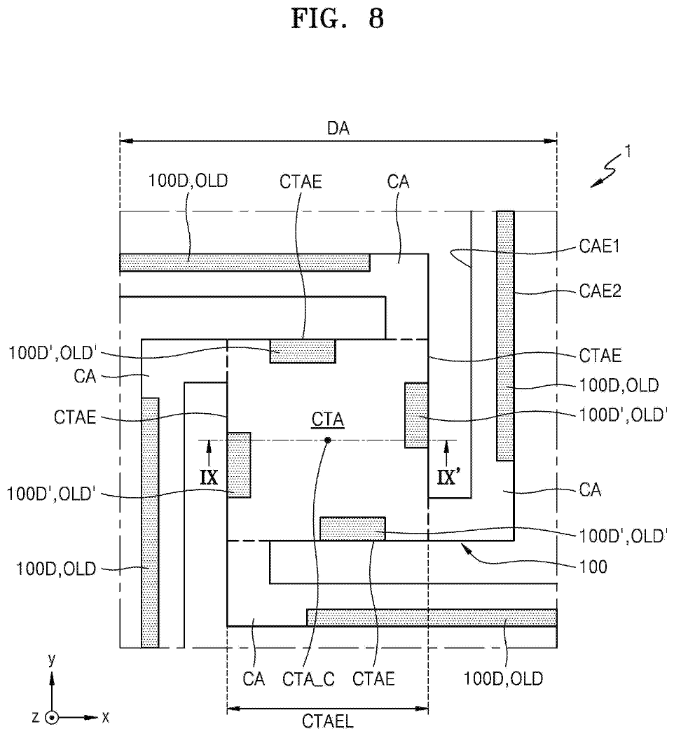

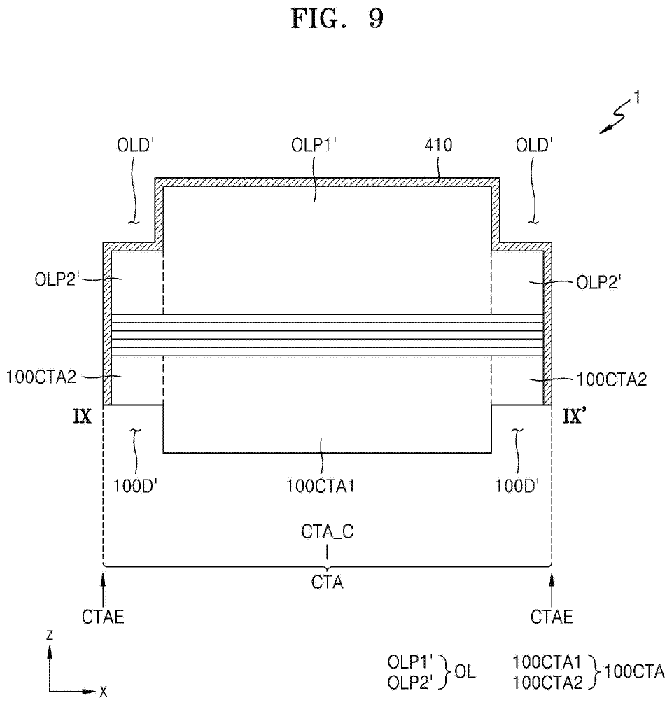

FIG. 8 is a plan view of a portion of the display area DA of the display apparatus 1 according to an embodiment, and FIG. 9 is a cross-sectional view of the display area DA, taken along line IX-IX′ of FIG. 8 according to an embodiment.

In an embodiment and as shown in FIG. 8, the display apparatus 1 includes the island portion CTA and the connection portion CA. The connection portion CA may include the concave portion 100D of the substrate 100 and/or the concave portion OLD of the organic insulating layer OL as described above with reference to FIGS. 7A and 7B.

In an embodiment, referring to FIG. 8, the island portion CTA of the display apparatus 1 may include a step difference. In an embodiment and as shown in FIG. 9, the island portion CTA of the display apparatus 1 may include the substrate 100 and the organic insulating layer OL, and at least one of the substrate 100, and the organic insulating layer OL may include a step difference.

In an embodiment, the island region 100CTA of the substrate 100 may include a first portion 100CTA1 corresponding to a center CTA_C of the island portion CTA, and a second portion 100CTA2 corresponding to sides CTAE of the island portion CTA. The second portion 100CTA2 may be formed to be relatively concave with respect to the first portion 100CTA1. In other words, the second portion 100CTA2 may form a step difference with respect to the first portion 100CTA1.

In an embodiment, the second portion 100CTA2 of the island region 100CTA of the substrate 100 may include a concave portion 100D′. A maximum value of the depth of the concave portion 100D′ may be about 5 μm.

In an embodiment, the organic insulating layer OL disposed opposite the substrate 100 may be arranged in the island region 100CTA of the substrate 100, and may include a first portion OLP1′ corresponding to the center CTA_C of the island portion CTA and a second portion OLP2′ corresponding to the sides CTAE of the island portion CTA. The second portion OLP2′ may be formed to be relatively concave with respect to the first portion OLP1′. In other words, the second portion OLP2′ may form a step difference with respect to the first portion OLP1′. The organic insulating layer OL may include the second organic insulating layer OL2 (see FIG. 5) and/or the third organic insulating layer OL3 (see FIG. 5) as described above with reference to FIG. 5.

In an embodiment, the second portion OLP2′ of the organic insulating layer OL may include a concave portion OLD′, and a maximum value of a depth of the concave portion OLD′ may be about 3 μm.

In an embodiment, the concave portions 100D′ of the substrate 100 and/or the concave portions OLD′ of the organic insulating layer OL provided to the island portion CTA of the display apparatus 1 may extend along the side CTAE of the island portion CTA and be located apart from each other. The length of each of the concave portion 100D′ of the substrate 100 and the concave portion OLD′ of the organic insulating layer OL provided to the island portion CTA may be less than a length CTAEL of one side CTAE of the island portion CTA.

According to an embodiment, a transformation rate of a portion of the display apparatus 1, for example, the connection portion CA due to external force applied to the display apparatus 1 may be reduced. This effect is provided as an example, and the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims. The embodiments disclosed in the present disclosure and illustrated in the drawings are provided as particular examples for more easily explaining the technical contents according to the present disclosure and helping understand the embodiments of the present disclosure, but not intended to limit the scope of the embodiments of the present disclosure. Accordingly, the scope of the various embodiments of the present disclosure should be interpreted to include, in addition to the embodiments disclosed herein, all alterations or modifications derived from the technical ideas of the various embodiments of the present disclosure. Moreover, the embodiments or parts of the embodiments may be combined in whole or in part without departing from the scope of the invention.

What is claimed is:

1. A stretchable display apparatus comprising:
a substrate including two island regions and a connection region, wherein the two island regions are located apart from each other and the connection region connects the two island regions to each other;
sub-pixel circuits arranged in the two island regions;
light-emitting diodes arranged in the two island regions and electrically connected to the sub-pixel circuits;
a wiring arranged in the connection region and electrically connected to the sub-pixel circuit arranged in a first island region which is one of the two island regions; and
an insulating layer disposed on the wiring,
wherein at least one of the connection region and the insulating layer includes a step difference.

2. The stretchable display apparatus of claim 1, wherein the connection region of the substrate has a first length extending in a lengthwise direction of the connection region and a first width that is directed perpendicular to the first length, and wherein the first length is greater than the first width.

3. The stretchable display apparatus of claim 2, wherein the connection region of the substrate includes:
a first portion located adjacent to the first island region; and
a second portion located away from the first island region, wherein the second portion has a thickness which is less than a thickness of the first portion.

4. The stretchable display apparatus of claim 3, wherein the second portion includes a concave portion with respect to the first portion, and wherein a maximum value of a depth of the concave portion is about 5 μm.

5. The stretchable display apparatus of claim 3, wherein a maximum value of a width of the second portion of the connection region of the substrate is about 0.5 times the first width.

6. The stretchable display apparatus of claim 2, wherein an insulating layer in the connection region of the substrate includes:
a first portion located adjacent to the first island region; and
a second portion located away from the first island region, wherein the second portion has a thickness which is less than a thickness of the first portion.

7. The stretchable display apparatus of claim 6, wherein the second portion includes a concave portion with respect to the first portion, and wherein a maximum value of a depth of the concave portion is about 3 μm.

8. The stretchable display apparatus of claim 6, wherein the insulating layer has a second width directed in a same direction as a direction of the first width, and wherein a maximum value of a width of the second portion of the insulating layer is about 0.5 times the second width.

9. The stretchable display apparatus of claim 1, wherein the insulating layer includes an organic insulating material.

10. The stretchable display apparatus of claim 9, wherein the insulating layer extends to the first island region of the substrate, and a portion of the insulating layer located in the first island region is disposed between a transistor of a sub-pixel circuit arranged in the first island region and a first electrode of a light-emitting diode electrically connected to the transistor.

11. The stretchable display apparatus of claim 1, wherein the first island region of the substrate includes a step difference located in an edge of the first island region.

12. A stretchable display apparatus comprising:
a plurality of island portions each including a sub-pixel circuit, and a light-emitting diode electrically connected to the sub-pixel circuit; and
a connection portion connecting two adjacent island portions among the plurality of island portions to each other,
wherein the connection portion includes:
a wiring electrically connected to a sub-pixel circuit of a first island portion, which is one of the two adjacent island portions;
a lower layer disposed under the wiring; and
an upper layer disposed on the wiring,
wherein at least one of the lower layer and the upper layer of the connection portion includes a step difference.

13. The stretchable display apparatus of claim 12, wherein the connection portion includes a first side and a second side, wherein the first side is located adjacent to the first island portion, and the second side is located away from the first island portion, and wherein,
at least one of the upper layer and the lower layer of the connection portion includes a first portion located adjacent to the first side; and
a second portion located adjacent to the second side, wherein the second portion includes a concave portion with respect to the first portion.

14. The stretchable display apparatus of claim 13, wherein a maximum value of a width of the second portion is about 0.5 times a width of the connection portion ranging from the first side of the connection portion to the second side.

15. The stretchable display apparatus of claim 13, wherein the lower layer of the connection portion includes the first portion and the second portion, and wherein a maximum value of a depth of the concave portion is about 5 μm.

16. The stretchable display apparatus of claim 13, wherein the upper layer of the connection portion includes the first portion and the second portion, and wherein a maximum value of a depth of the concave portion is about 3 μm.

17. The stretchable display apparatus of claim 12, wherein the lower layer is a substrate including a polymer resin.

18. The stretchable display apparatus of claim 12, wherein the upper layer is an organic insulating layer.

19. The stretchable display apparatus of claim 12, wherein the first island portion includes a first lower layer and a first upper layer, wherein the first lower layer includes a same material as a material of the lower layer of the connection portion, and the first upper layer includes a same material as a material of the upper layer of the connection portion, and
at least one of the first lower layer and the first upper layer of the first island portion includes a step difference.

20. The stretchable display apparatus of claim 12, further including an insulating layer disposed on the wiring.
